(19) United States
(12) Patent Application Publication
(10) Pub. No.: US 2004/0230882 A1
(43) Pub. Date: Nov. 18, 2004

(54) Pseudo random LBIST controls

(75) Inventors: William V. Huott, (US); Timothy J. Koprowski, Newburgh, NY (US); Peilin Song, Lagrangeville, NY (US)

Correspondence Address: Lynn L. Augspurger, IBM Corporation, 2455 South Road, P386, Poughkeepsie, NY, 12601, US

(73) Assignee: International Business Machines Corporation, Armonk, NY

(21) Appl. No.: 10/436,220

(22) Filed: May 12, 2003

(51) Int. Cl. G01R 31/28

(52) U.S. Cl. 714/733

(57) ABSTRACT

Pseudo-Random Controls are added to an LBIST design which allow for the system clock sequence, scan (A/B) clock sequence, PRPG weighting and PRPG clock gating to vary during the LBIST test. An LFSR is added to the LBIST control logic to generate pseudo-random data that is multiplexed with the existing fixed value control parameters. Weight logic is also added to the LFSR output which gives certain control parameter settings a higher probability of occuring during the LBIST test.

### RELATED APPLICATIONS

References is made herein to a related application, namely reference 1 of T. Koprowski, et al., “Programmable LBIST Channel Weighting and Weight Selection”, U.S. Ser. No. 09/671,413 filed Nov. 27, 2000.

### FIELD OF THE INVENTION

This invention relates to integrated circuits having logic circuits and particularly is directed to a method for controlling LBIST (Logic Built-In Self Test) and the controls that are used to exercise the LBIST circuits for testing these logic circuits.

This co-pending applications and the present application are owned by one and the same assignee, International Business Machines Corporation of Armonk, N.Y.

The descriptions set forth in these co-pending applications are hereby incorporated into the present application by this reference.

Trademarks: IBM® is a registered trademark of International Business Machines Corporation, Armonk, N.Y., U.S.A. Other names may be registered trademarks or product names of International Business Machines Corporation or other companies.

### BACKGROUND

IBM's Logic Built In Self Test (LBIST) is used to test the integrated circuit logic of high-end servers and computers. LBIST is used at all levels of testing including: integrated circuit, MCM (Multiple Chip Module) and system. One of the major advantages that LBIST has over other means of testing logic is that the operation of the test is self-contained. All of the circuitry required to execute the test at-speed is contained within the integrated circuit. Very limited external controls are needed, so LBIST can be run at all levels of packaging (wafer, TCA—Temporary Chip Attach, module and system) without requiring expensive external test equipment.

LBIST utilizes what is commonly referred to Self-Test Using MISR and Parallel SRSG (STUMPS) architecture (see ref. 1. P. H. Bardell and W. H. McAnney, “Self-Testing of Multichip Modules,” Proceedings of the IEEE International Test Conference, 1982, pp. 200-204.), where MISR and SRSG stand for Multiple Input Signature Register and Shift Register Sequence Generator, respectively. The major components of LBIST include: a pseudo-random pattern generator (PRPG) used to generate the test patterns; MISR to compress the test results; and the self-test control macro (STCM) that is used to apply the clocks and controls to the PRPG, MISR and system logic to perform the test. The PRPG applies pseudo-random test data to the system logic via multiple parallel scan chains which are connected between the PRPG and MISR. In the basic configuration, the probability of the test data being a ‘0’ or ‘1’ is 50%. See FIG. 1.

In order to improve the test coverage of LBIST, weighting logic has been added to the LBIST design which increases the probability of an output of the PRPG being a ‘1’ or ‘0’ (see ref. 2. T. Koprowski, et al., “Programmable LBIST Channel Weighting and Weight Selection”, U.S. Ser. No. 09/671,413 filed Nov. 27, 2000). The application of weighted LBIST patterns after standard flat random LBIST patterns increases the test coverage by allowing LBIST to test logic that is random resistant. AND gates with many inputs and OR gates with many inputs are typical random resistant structures that benefit from weighted data which has a higher probability of being a ‘1’ or ‘0’. Testing a large AND gate benefits from data weighted towards a ‘1’, while testing a large OR benefits from data weighted towards a ‘0’. See FIG. 2. Different levels of weighting can be also be applied. A small AND structure might require a weight of ¾ (75% chance of being a ‘1’) whereas a large AND structure might require a weight of 31/32 or higher.

In addition to applying multiple weight sets, different clocks sequences are also applied to the system latches to improve test coverage. In a standard LSSD Master/Slave latch configuration (see ref. 3. E. B. Eichelberger, “Method of Level Sensitive Testing a Functional Logic System,” U.S. Pat. No. 3,761,695, Sep. 25, 1973; and 4. E. B. Eichelberger, “Level Sensitive Logic System,” U.S. Pat. No. 3,783,254, Jan. 1, 1974; and 5. E. B. Eichelberger and T. W. Williams, “A logic Design Structure for LSI Testability,” Proceedings of the 14th Design Automation Conference, New Orleans, 1977, pp. 462-468.) a C2C1 clock sequence is used to detect a large portion of the faults, however, other clock combinations such as C1C2, C2C1C2C1, C2C1C2, etc. may be needed to test logic not using standard LSSD latch configurations or to overcome latch adjacency problems. Also, the scan sequence used to load the system latches with data from the PRPG needs to be varied in order to detect different classes of faults. In some cases a skewed scan load sequence (ABABAB . . . ABA) is required where the data in the Master and Slave latches has a 50% chance of being different and/or a skewed unload scan sequence (BABABAB . . . AB) is require to observe the data in the Master latch.

We found that using the prior practices in order to achieve the highest levels of test coverage, many different LBIST tests are required utilizing different combinations of flat random patterns, weighted random patterns, scan clock sequences and system clock sequences.

### SUMMARY OF THE INVENTION

In accordance with our improvements, higher test coverage can be obtained with a method for testing integrated circuits having logic circuits and particularly is directed to a method for controlling LBIST (Logic Built-In Self Test) and the controls that are used to exercise the LBIST circuits for testing these logic circuits, comprising a method whereby LBIST control parameters are generated from an LFSR within the LBIST controls such that they will vary throughout the LBIST test and be pseudo-random and predictable. In accordance with the preferred embodiment of the inveniton the system clocks sequence is varied by the LFSR output on each LBIST pattern within the LBIST test. Also, in accordance with the preferred embodiment, the scan sequence skewed load/unload setting is varied by the LFSR output on each LBIST pattern within the LBIST test. Enabling of PRPG weighting is varied by the LFSR output on each LBIST pattern within the LBIST test. PRPG weight selection is varied by the LFSR output on each LBIST pattern within the LBIST test, as the PRPG clock is gated by the LFSR output on each A/B clock cycle within the LBIST test.

The weighting provisions of an embodiment of the invention, enables LBIST control parameters to be generated from the weighted output of an LFSR within the LBIST controls such that they will vary throughout the LBIST test and be pseudo-random and predictable. In this weighted embodiment, the system clocks sequence is varied by the weighted LFSR output on each LBIST pattern within the LBIST test and the scan sequence skewed load/unload setting is varied by the weighted LFSR output on each LBIST pattern within the LBIST test. The enabling of PRPG weighting is varied by the weighted LFSR output on each LBIST pattern within the LBIST test. The PRPG weight selection is varied by the weighted LFSR output on each LBIST pattern within the LBIST test and the PRPG clock is gated by the weighted LFSR output on each A/B clock cycle within the LBIST test.

These and other improvements are set forth in the following detailed description. For a better understanding of the invention with advantages and features, refer to the description and to the drawings.

### DESCRIPTION OF THE DRAWINGS

FIG. 1 is a block diagram of a typical prior art STUMPS architecture with LBIST.

FIG. 2 is a block diagram of a typical prior art STUMPS architecture with weighted LBIST.

FIG. 3 illustrates pseudo-random LBIST controls along with the various LBIST control signals to which it can be applied.

FIG. 4 illustrates pseudo-random LBIST controls with weighting logic along with the various LBIST control signals to which it can be applied.

FIG. 5 shows an example of weighted logic that can be used as part of the pseudo-random LBIST controls shown in FIG. 4.

Our detailed description explains the preferred embodiments of our invention, together with advantages and features, by way of example with reference to the drawings.

### DETAILED DESCRIPTION OF THE INVENTION

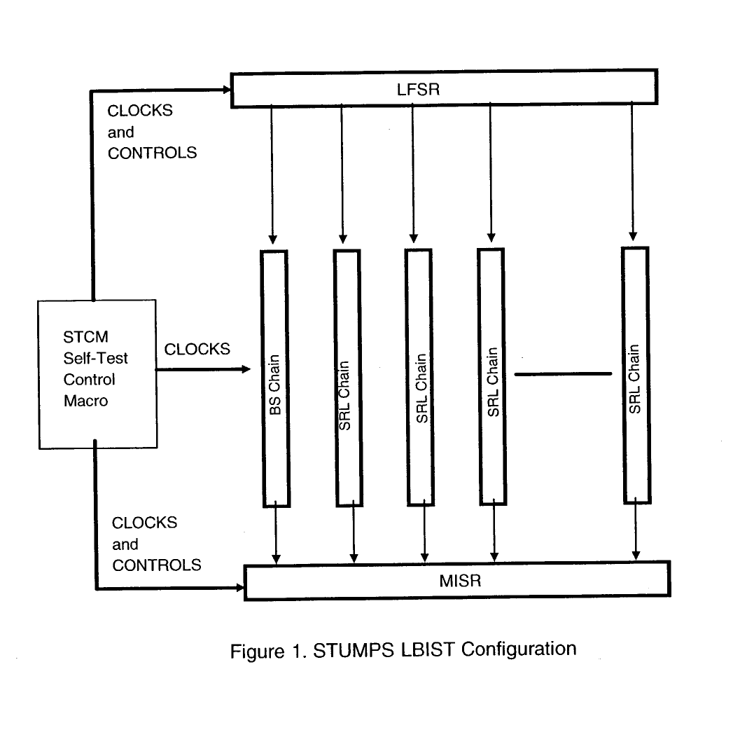

The standard LBIST STUMPS configuration is shown in FIG. 1 where the chip scan chains 1,2 are loaded with scan data from the PRPG 3 and the outputs of the scan chains 1,2 are fed to and compressed into the MISR 4. All of the controls and clocks for the LBIST operation are generated by the Self-Test Control Macro (STCM) 5.

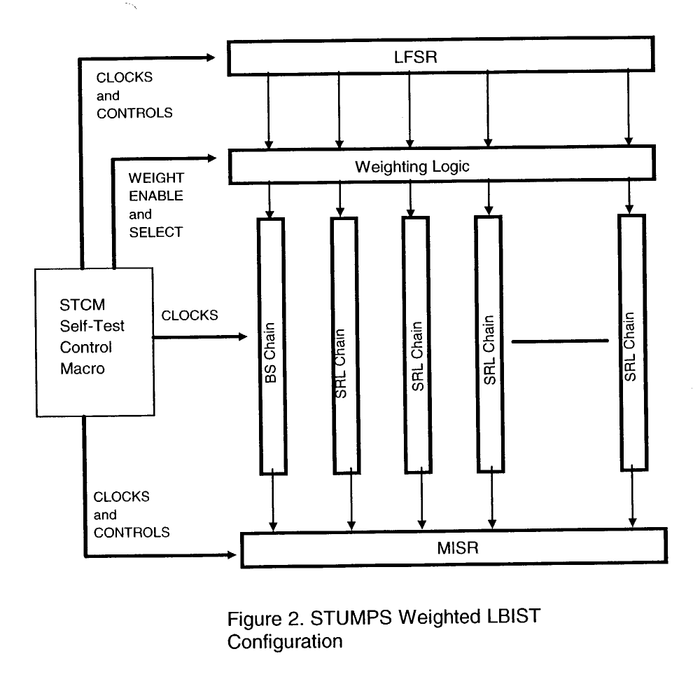

FIG. 2 shows the same LBIST STUMPS configuration with weighting logic 6 that is used to adjust the probability of the data from the PRPG being a ‘1’ or ‘0’. The weighting logic 6 is also controlled from the STCM.

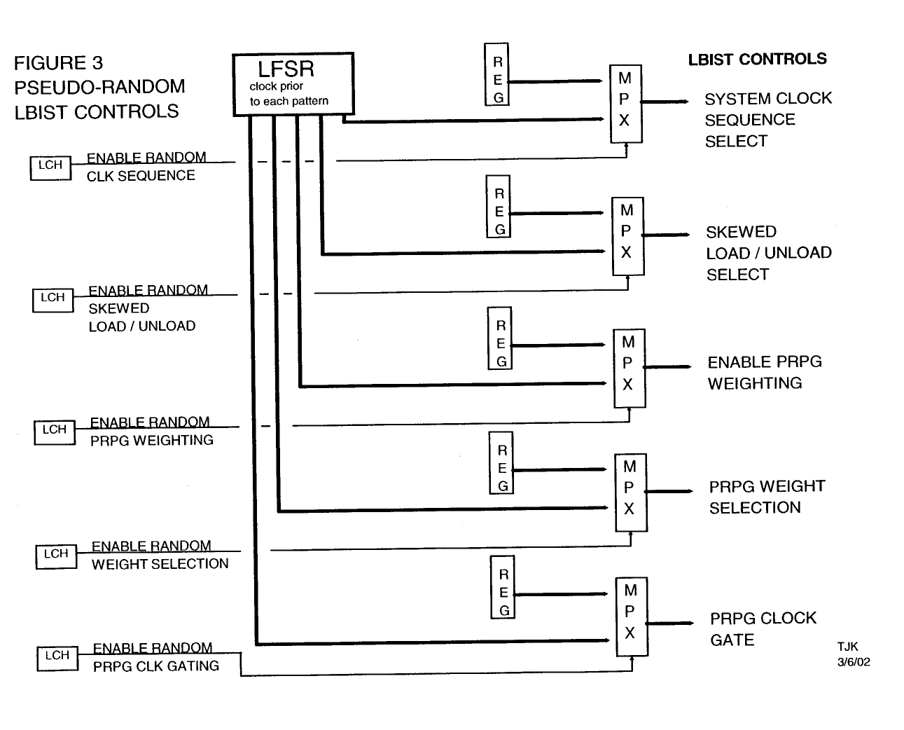

The Pseudo Random LBIST Controls are depicted in FIG. 3 and shown to be an extension of LBIST and an integral part of the LBIST controls which are contained in the STCM 6 of FIGS. 1 and 2.

In the existing LBIST design, the different LBIST control signals are fixed throughout the the LBIST test sequence. These fixed values are specified for the System Clock Sequence, Skewed Load/Unload scan selection, whether or not Weighting is to be used on the output of the PRPG, the weight to be used if weighting is enabled and gating controls for the PRPG clocks. These fixed values are stored in the Registers 1, 2, 3, 4, 5 respectively.

When using the Pseudo random LBIST controls, some or all of these control values will will no longer be fixed. The control values will now be obtained from an Linear Feedback Shift Register (LFSR) 16 that resides within the LBIST STCM. The LFSR 16 will generate random but predictable data (hence the term pseudo-random) and is clocked each time an A/B scan clock pair is generated. For some of the controls (System clock sequence, Skewed load/unload scan selection, PRPG weight enable and PRPG weight selection), the values must remain stable for each LBIST pattern. In these cases, registers 17, 18, 19, 20 are added that are clocked prior to each LBIST pattern. For the case of PRPG clock gating, this operation is done on each A/B clock cycle so no register is needed.

The enable latches 11, 12, 13, 14, 15 define the LBIST controls that are to be pseudo-random and contain fix values for the entire LBIST test. These latches select which port of the multiplexers 6, 7, 8, 9, 10 is used for the respective control value, either a fixed value from the registers 1, 2, 3, 4, 5 or values from the LFSR 16.

The LFSR 16 is updated for each A/B clock pair so the data for each of the pseudo-random controls can change for each A/B clock cycle or LBIST pattern as required.

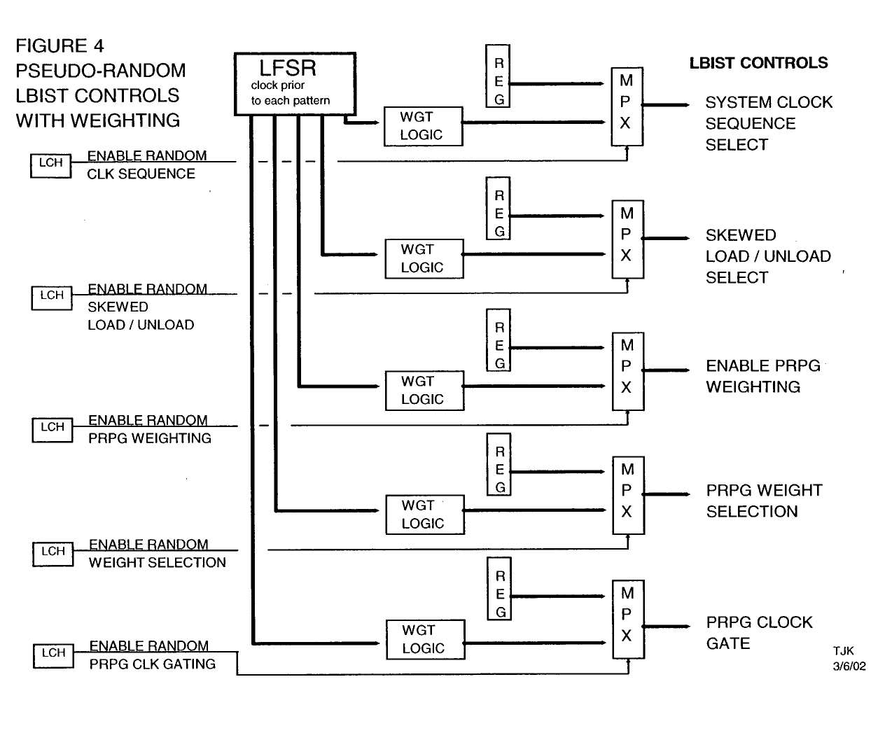

FIG. 4 shows the addition of weighting logic 21, 22, 23, 24, 25 for each of the LBIST pseudo random controls. This logic can be used when it is determined to be more beneficial to have certain LBIST-controls more likely being in one state over another. The weight logic can be used, for example, to increase the probability that a certain system clock sequence is used or that a certain weight selection is less likely to occur.

The data from the LFSR 16 is applied to the weight logic 21, 22, 23, 24, 25 and the weighted logic output is applied to the registers 17, 18, 19, 20 or multiplexer 10 as required.

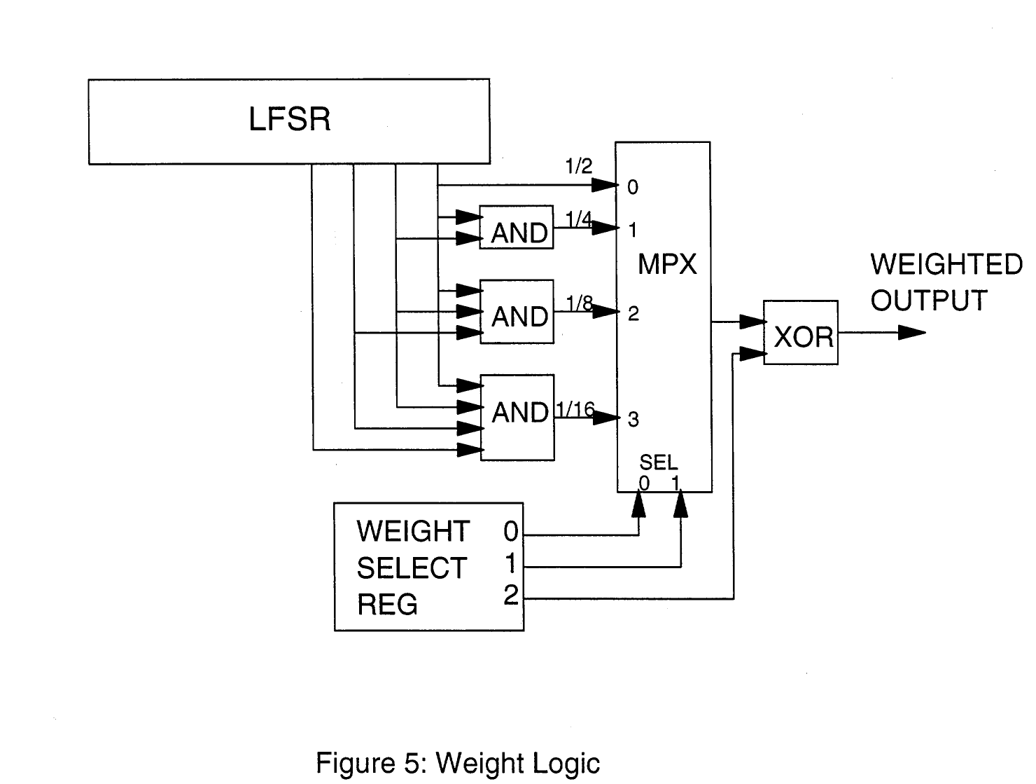

FIG. 5 shows an example of weight logic where different bits from the LFSR 7 are ANDed together by AND gates 1, 2, 3 and the resultant bits applied to the input of a multiplexer 5. The port of the multiplexer that is selected is determined by the weight select register 4. The output of the multiplexer 5 feeds an XOR gate 6 which allows for the weight value to be inverted based on the state of bit 2 of the weight select register 4. The output of the weight logic is used as decribed above in the discussion on FIG. 4.

It is obvious that different weights can be generated by changing the size of the AND gates 1, 2, 3 or that additional weights can be used by increasing the size of the multiplexer 5 and weight select register 4.

After this review of the drawings, it will be appreciated that current implementations of LBIST contain registers within the STCM that define whether LBIST weighting is enable, the selected weight, the system clock sequence and the scan sequence. These registers are initialized for each LBIST test when the entire chip is loaded via a scan operation with data that defines the LBIST test to be performed including data defining each of the parameters described above. After the chip is initialized for LBIST, the STCM state machine is started and executes the programmed LBIST test for a defined number of cycles after which the MISR is read to determine whether or not the LBIST test passed. Each different LBIST test requires unique setup data and a unique MISR signature that is compared at the end of the test to determine if the test passed.

Due to the random nature of the data applied from the PRPG, many LBIST patterns are required to achieve the required test coverage. A pattern is defined as a load of the system latches from the PRPG via scan clocks followed by a system clock sequence followed by an unload of the system latch data into the MISR via scan clocks (NOTE: The load and unload sequences are combined for consecutive patterns by combining the unload sequence of pattern N with the load sequence of pattern N+1). The time it takes to run each LBIST test is determined by the length of the internal STUMPS channels and the number of patterns applied within the test and the cost of testing a chip is proportional to the amount of time it takes to run the tests. As more LBIST tests are applied to achieve higher test coverage, the time for test increases and, hence, the cost.

In some instances, such as system power on testing, the time allocated for testing is pre-determined. The test coverage is limited by the amount of testing that can be accomplished in the specified time. In many cases only 1 or 2 LBIST tests can be run, so the most effective test(s) are chosen for the application.

This method of our invention overcomes these described limitations by allowing some or all of the LBIST controls to be “randomized” within a given LBIST test. A Linear Feedback Shift Register (LFSR) is added to the STCM to generate pseudo-random data that can be used to specify the various LBIST controls. (Pseudo-random data is defined as data that appears random but is predictable and repeatable. A maximal length configured LFSR generates pseudo-random data). The data specifying the various LBIST controls is now taken from bits in the LFSR rather than a static register as shown in FIG. 3.

Each of the LBIST controls can be defined to be pseudo-random or static depending on the degree of “randomness” that is desired within the LBIST test by setting an enable latch for each of the LBIST controls. The STCM LFSR can be clocked or advanced prior to each pattern as shown in FIG. 3 or could be clocked with the same scan clocks used to load the system latches and simply snapshot the required bits into registers prior to the start of each pattern. This invention allows many different weights, scan sequences and system clock sequences to be combined into a single LBIST test.

An extension of this method is shown in FIG. 4. It could be determined that certain clock sequences or weights are more effective for increasing test coverage on a particular chip. In this case, weighting logic could be added to the output of the STCM to insure that certain clock sequences or weights would occur with higher probability when running with the pseudo-random LBIST controls. This weighting could be static or programmable depending on the level of complexity desired in the STCM design or the available chip area allowed for test function.

An example of weighting logic is shown if FIG. 5. In this case, 4 bits from an LFSR are used and “ANDed” together in different combinations to achieve different probabilities of the resultant “ANDed” bit being a ‘1’ or ‘0’. Each bit of an LFSR is pseudo-random, so the probability of being a ‘1’ is ½. If 2 of the bits are “ANDed” together the probability of being a ‘1’ becomes ¼. If 3 bits are “ANDed” together the probability becomes ⅛ and so forth. Weight select bits are used to select the probability or “weight” that is needed for the particular test and are set in a register prior to the test. Weight bits 0,1 select the probability and weight bit 2 is used to invert the probability using and XOR gate. As an example if weight bits 0,1 are set to 10, the weight selected is ⅛. Weight bit 2 can be used to invert that probability to ⅞ if it is set to ‘1’ since the XOR will invert the output of the multiplexer.

Although the test coverage of this single test may not achieve the same level of coverage achieved by many separate LBIST tests, the total test time required to achieve a particular level of coverage should be substantially reduced. Also, it is not necessary to combine all of the LBIST tests into 1 test. These improvements can be used to simply reduce the number of LBIST tests by only randomizing certain LBIST controls within each test.

In the situation where the test time is fixed, the combination of LBIST controls made possible by this invention can be adjusted to achieve the highest possible test coverage within the allotted time. Certain weights or clock sequences that have shown to achieve high levels of coverage could be enabled within the pseudo-random LBIST test.

Another application for the preferred embodiment of the invention would be its application in diagnostics on a chip that passes all tests but fails in system operation. Current approaches take existing LBIST patterns and extend the number of patterns applied (or change the PRPG seeds), then apply them to both a known good chip and the failing chip and compare MISR signatures. This is known as the Golden Signature approach. Unfortunately, many different LBIST patterns need to be updated and applied to find the fail. With this invention, a single “super” LBIST test could be created with all LBIST controls randomized and applied using the Golden Signature approach.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method used for testing integrated circuits having logic circuits LBIST (Logic Built-In Self Test) circuits and controls that are used to exercise the LBIST circuits for testing the logic circuits, comprising steps for LBIST testing including a step of
generating LBIST control parameters from an LFSR (Linear Feedback Shift Register) within the LBIST controls such that they will vary throughout the LBIST test and be pseudo-random and predictable.

2. The method of claim 1 wherein further during testing integrated circuit system's clock sequence is varied by the LFSR output on each LBIST pattern within the LBIST test.

3. The method of claim 1 wherein further during testing the LFSR output on each LBIST pattern within said LBIST test varies the scan sequence skewed load/unload setting during said LBIST testing.

4. The method of claim 1 wherein further during testing the LFSR output on each LBIST pattern within the LBIST test varies PRPG (Pseudo Random Patter Generator) weighting.

5. The method of claim 1 wherein further during testing the LFSR output on each LBIST pattern within the LBIST test varies PRPG (Pseudo Random Patter Generator) weight selection.

6. The method of claim 1 wherein further during testing the LFSR output on each LBIST pattern within the LBIST test varies PRPG (Pseudo Random Patter Generator) weight selection as the PRPG clock is gated by the LFSR output on each A/B clock cycle within the LBIST test.

7. A method used for testing integrated circuits having logic circuits LBIST (Logic Built-In Self Test) circuits and controls that are used to exercise the LBIST circuits for testing the logic circuits, comprising steps for LBIST testing including a step of
generating LBIST control parameters from a weighted output of an LFSR (Linear Feedback Shift Register) within the LBIST controls such that they will vary throughout the LBIST test and be pseudo-random and predictable.

8. The method of claim 7 wherein further during testing integrated circuit system's clock sequence is varied by the LFSR output on each LBIST pattern within the LBIST test.

9. The method of claim 8 wherein further during testing the LFSR output on each LBIST pattern within said LBIST test varies the scan sequence skewed load/unload setting during said LBIST testing.

10. The method of claim 9 wherein further during testing the LFSR output on each LBIST pattern within the LBIST test varies PRPG (Pseudo Random Patter Generator) weighting.

11. The method of claim 10 wherein further during testing the LFSR output on each LBIST pattern within the LBIST test varies PRPG (Pseudo Random Patter Generator) weight selection.

12. The method of claim 11 wherein further during testing the PRPG (Pseudo Random Patter Generator) weight selection is varied as the PRPG clock is gated by the LFSR output on each A/B clock cycle within the LBIST test.

13. The method of claim 7 wherein said LFSR is part of said LBIST control logic and is exercised to generate pseudo-random data that is multiplexed with fixed value control parameters.

14. The method of claim 7 wherein said LFSR and weighting logic is part of said LBIST control logic for providing an LFSR output which gives certain control parameter settings a weighted higher probability of occuring during the LBIST test.
